(19) United States
(12) Patent Application Publication
(10) Pub. No.: US 2008/0192412 A1
(43) Pub. Date: Aug. 14, 2008

(54) Flat display panel frame

(75) Inventor: Wen-Chin Tsai, Jhubei City (TW)

Correspondence Address: ABELMAN, FRAYNE & SCHWAB, 666 THIRD AVENUE, 10TH FLOOR, NEW YORK, NY, 10017, US

(73) Assignee: JOCHU TECHNOLOGY CO. LTD. (a corporation of Taiwan R.O.C.)

(21) Appl. No.: 11/705,923

(22) Filed: Feb. 13, 2007

(51) Int. Cl. H05K 5/00

(52) U.S. Cl. 361/679

(57) ABSTRACT

The present invention provides an improved flat display panel frame, wherein two L-shape workpieces or four strip-like workpieces are butt-jointed to form a frame body, and the perimeter of the frame body is bent to form an external bent portion, and thus, an flat display panel frame is completed. In the present invention, as the frame body is formed via butt-jointing multiple workpieces, the punching process for the metallic workpiece is more flexible, and an optimal workpiece arrangement can be used to achieve the highest manipulation efficiency of material. Thus, the material is saved, and the material cost is reduced. Further, the scrap is decreased, and the scrap-processing cost is also reduced.

### BACKGROUND OF THE INVENTION

1. Field of the Invention

The present invention relates to an improved flat display panel structure, particularly to an improved LCD panel frame, which may be used as a TFT-LCD or other flat display front panel frame and a backlight module frame thereof.

2. Description of the Related Art

In general, a TFT-LCD (Thin Film Transistor-Liquid Crystal Display) panel essentially includes a CF (Color Filter) substrate, a TFT substrate and a backlight module; which are assembled together with a combination of a metallic frame and a plastic frame. The plastic frame is a base for accommodating the elements and modules, and the metallic frame is used to press those elements and modules securely and simultaneously grip the plastic frame fixedly.

A conventional metallic frame is formed via punching off the central portion of a whole metallic plate, and the size of the central portion is identical to that of the panel. As shown in FIG. 1A, a metallic coil 10 is cut into multiple metallic plates 12. As shown in FIG. 1B, some redundant portions of the perimeter of the metallic plate 12 are punched/clipped off, and the punched/clipped off material is treated as the scrap. As shown in FIG. 1C, the perimeter of the metallic plate 12 is bent to form the bent edges 14. As shown in FIG. 1D, the central portion of the metallic plate 12 is punched off to form a panel window 16, and the panel is exposed through the panel window 16.

In the conventional technology, the metallic plate is processed using the punching and edge-clipping methods, and then, the central portion thereof is cut off to form a conventional metallic frame; those removed metallic pieces are regarded as scraps and needed to be processed otherwise. As the size of display panel is growing persistently, the area of the cut-off central portion of the metallic plate also becomes larger and larger and may reach two thirds of the area of the metallic plate. Thus, the cut-off material weighs more and more in the material cost.

Accordingly, the present invention proposes an improved LCD panel frame to overcome the abovementioned problems.

### SUMMARY OF THE INVENTION

One object of the present invention provides an improved flat display panel frame, whereby the material can be effectively saved, and the manipulation efficiency of material can be promoted, and thus, the material cost can be lowered.

Another object of the present invention provides an improved flat display panel frame, whereby the material can be used efficiently, and the material needs to be transported is decreased, and thus, the transportation cost of the material can be reduced.

Another object of the present invention provides an improved flat display panel frame, whereby the amount of scrap is reduced and so as to benefit environmental protection.

To achieve the abovementioned objects, the present invention proposes an improved flat display panel frame, wherein two L-shape workpieces or four strip-like workpieces are butt-jointed to form a frame body, and the perimeter of the frame body is bent to form an external bent portion, and thus, a frame structure is completed.

To enable the objects, technical contents, and characteristics of the present invention, the embodiments of the present invention are to be described in detail in cooperation with the attached drawings below.

### BRIEF DESCRIPTION OF THE DRAWINGS

FIG. 1A to FIG. 1D are diagrams schematically showing the fabrication steps of a conventional LCD panel frame.

FIG. 2A to FIG. 2D are diagrams schematically showing the fabrication steps of the LCD panel frame according to one embodiment of the present invention.

FIG. 3 is a diagram schematically showing the frame body formed of L-shape workpieces according to another embodiment of the present invention.

FIG. 4 is a diagram schematically showing the frame body formed of strip-like workpieces according to another embodiment of the present invention.

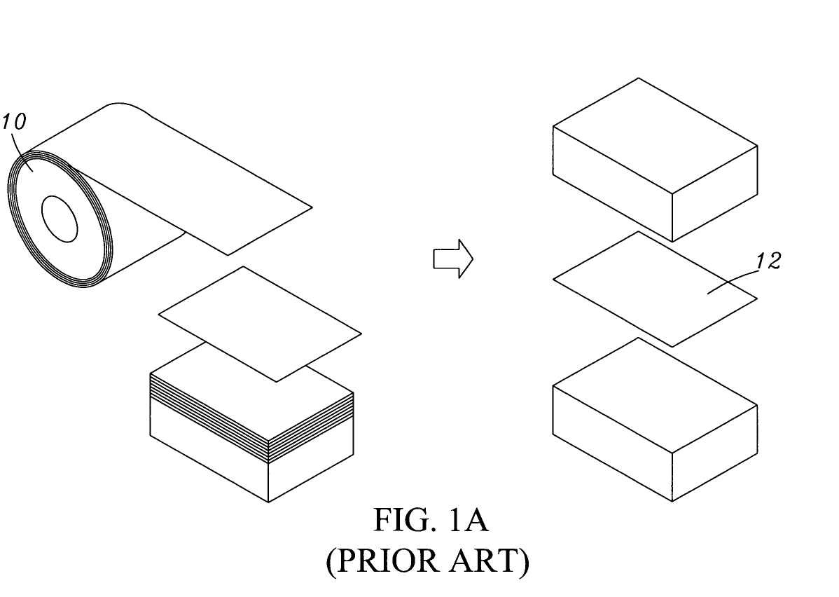

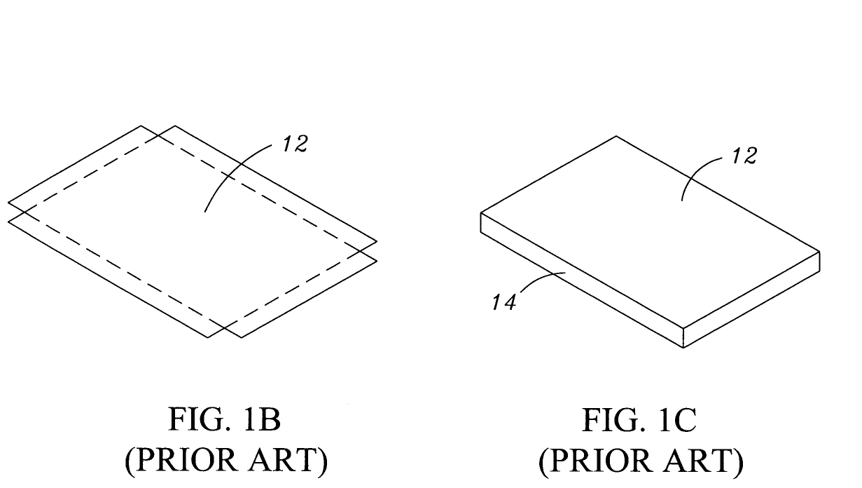

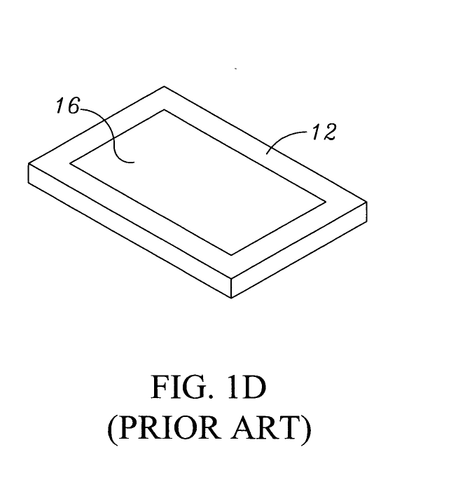

### DETAILED DESCRIPTION OF THE INVENTION

The present invention is to propose an improved flat display panel frame to overcome the low manipulation efficiency of material in the conventional technology that the LCD panel frame is formed via punching off the central portion of a whole metallic plate. In the present invention, a metallic sheet is punched into multiple L-shape or strip-like workpieces, and the workpieces are assembled into a frame body, and the frame body is then fabricated into a frame structure. Thereby, a high manipulation efficiency of material can be achieved for the fabrication of flat display panel frame.

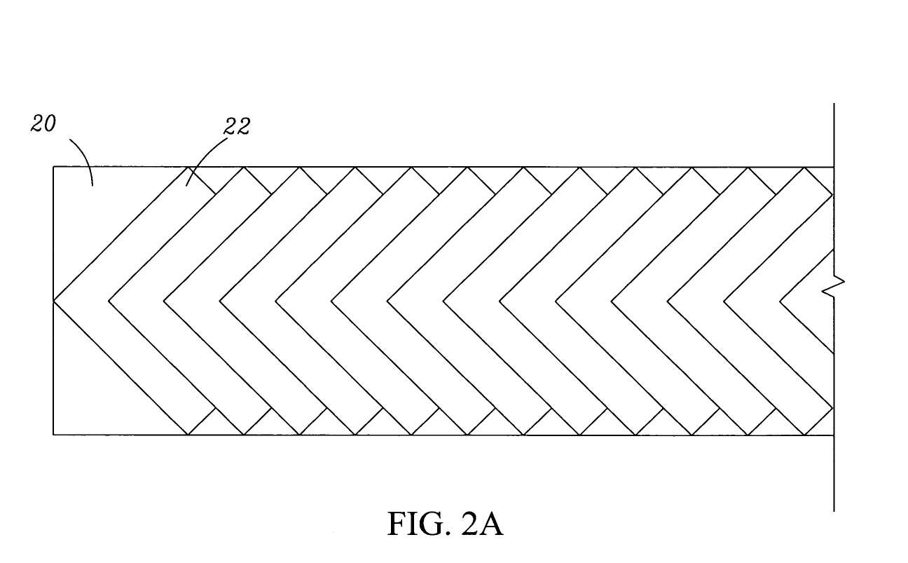

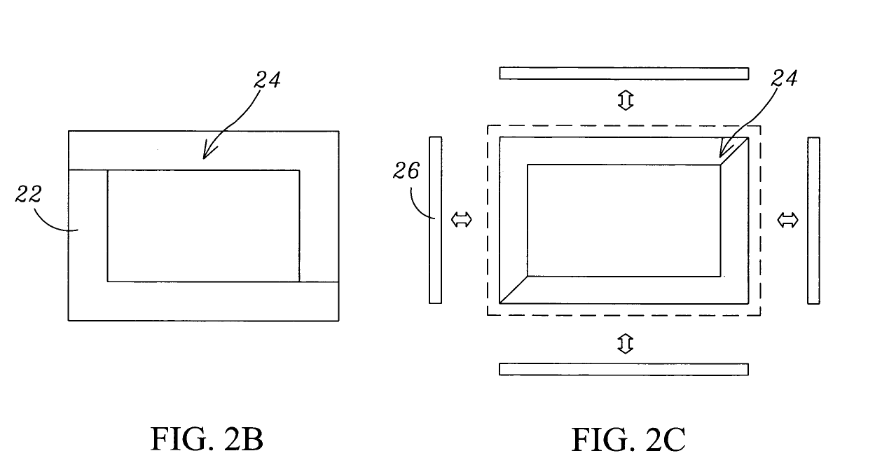

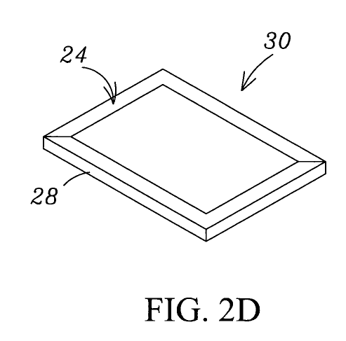

Please refer to FIG. 2D, which is a perspective-view diagram schematically showing the frame structure of the present invention. As shown in FIG. 2D, two L-shape workpieces 22 are butt-jointed via a riveting, soldering, brazing or welding method to form a frame body 24, and the perimeter of the frame body 24 is bent to form an external bent portion 28, and an LCD panel frame 30 is thus completed. When the butt-joint is implemented using the welding method, an anti-rust agent or an anti-rust paint is applied to the butt-jointed regions to prevent the rusting resulting from the welding.

A fabrication embodiment is used to demonstrate the characteristic of the high manipulation efficiency of material of the present invention below. Firstly, as shown in FIG. 2A, a whole metallic sheet 20 is punched into multiple L-shape workpieces 22. Next, as shown in FIG. 2B, each two workpieces 22 are jointed to form a frame body 24 via the riveting, soldering, brazing or welding method. The central empty portion of the frame body 24 is used as a panel window with a size slightly smaller than that of the panel, and the panel is exposed through the panel window.

Owing to the soldering, brazing, or welding process, the jointed regions are apt to rust. An anti-rust agent or an anti-rust paint may be applied to the butt-jointed regions between the L-shape workpieces 22 to prevent rusting.

Next, as shown in FIG. 2C, the redundant scraps 26 along the perimeter of the frame body 24 are trimmed off to adjust the frame body 24 to a correct dimension. Then, as shown in FIG. 2D, the perimeter of the frame body 24 is bent to form an external bent portion 28, and an LCD panel frame 30 is thus completed.

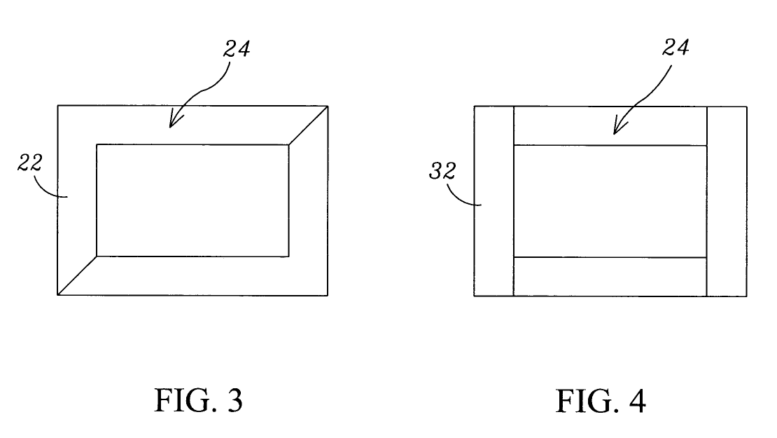

In the embodiment mentioned above, the frame body 24 is formed via butt-jointing two L-shape workpieces 22 with the butt-jointed ends being square, as shown in FIG. 2B. In another embodiment of the present invention, the frame body 24 is formed via butt-jointing two L-shape workpieces 22 with the butt-jointed ends being oblique, as shown in FIG. 3. In another embodiment of the present invention, a metallic sheet is cut into multiple strip-like workpieces 32, and four strip-like workpieces 32 are butt-jointed to form a frame body 24, as shown in FIG. 4; the butt-jointed ends in this embodiment may also be either square or oblique.

The improved flat display panel frame of the present invention can effectively promote the manipulation efficiency of material, save the material, decrease the scrap, and reduce the material cost of the flat display panel frame. Further, as the amount of required material is decreased, the transportation cost is also reduced. Besides, as the amount of scrap is lowered, the scrap-processing cost is reduced, and the environmental protection is also benefited.

Those embodiments of the present invention described above are to clarify the technical thoughts and characteristics of the present invention in order to enable the persons skilled in the art to understand, make, and use the present invention. However, it is not intended to limit the scope of the present invention. Any equivalent modification and variation according to the spirit of the present invention is to be also included within the scope of the present invention.

What is claimed is:

1. An improved flat display panel frame comprising a frame body formed via butt-jointing two L-shape workpieces or four strip-like workpieces and having an external bent portion along the perimeter thereof.

2. The improved flat display panel frame according to claim 1, wherein said two L-shape workpieces or said four strip-like workpieces are formed of metallic material via a punching method.

3. The improved flat display panel frame according to claim 1, wherein said two L-shape workpieces or said four strip-like workpieces are squarely butt-jointed.

4. The improved flat display panel frame according to claim 1, wherein said two L-shape workpieces or said four strip-like workpieces are obliquely butt-jointed.

5. The improved flat display panel frame according to claim 1, wherein said two L-shape workpieces or said four strip-like workpieces are butt-jointed via a riveting, soldering, brazing or welding method.

6. The improved flat display panel frame according to claim 1, wherein an anti-rust agent or an anti-rust paint is applied to the butt-jointed regions of said two L-shape workpieces or said four strip-like workpieces.
